(19) United States
(12) Patent Application Publication
(10) Pub. No.: US 2026/0018478 A1
(43) Pub. Date: Jan. 15, 2026

(54) MOISTURE RESISTIVE FLIP-CHIP BASED MODULE

(71) Applicant: Qorvo US, Inc., Greensboro, NC (US)

(72) Inventors: Tarak A. Railkar, Plano, TX (US); Kevin J. Anderson, Plano, TX (US); Bror Peterson, Fairview, TX (US); Andrew Arthur Ketterson, Dallas, TX (US); Deep C. Dumka, Richardson, TX (US)

(21) Appl. No.: 19/215,810

(22) Filed: May 22, 2025

Related U.S. Application Data
(60) Provisional application No. 63/670,302, filed on Jul. 12, 2024.

(51) Int. Cl. H01L 23/31; H01L 21/56; H01L 23/00; H01L 23/16; H01L 23/29; H01L 23/367

(52) U.S. Cl. CPC H01L 23/315; H01L 21/565; H01L 23/16; H01L 23/3121; H01L 23/3135; H01L 23/3675; H01L 23/564; H01L 24/10; H01L 24/16; H01L 24/32; H01L 24/73; H01L 23/291; H01L 23/293; H01L 24/81; H01L 24/92; H01L 2224/10126; H01L 2224/16225; H01L 2224/32225; H01L 2224/32245; H01L 2224/73253; H01L 2224/81191; H01L 2224/81815; H01L 2224/92225

(57) ABSTRACT

The present disclosure relates to a flip-chip based moisture-resistant module, which includes a substrate with a top surface, a flip-chip die, a sheet-mold film, and a barrier layer. The flip-chip die has a die body and a number of interconnects, each of which extends outward from a bottom surface of the die body and is attached to the top surface of the substrate. The sheet-mold film directly encapsulates sides of the die body, extends towards the top surface of the substrate, and directly adheres to the top surface of the substrate, such that an air-cavity with a perimeter defined by the sheet-mold film is formed between the bottom surface of the die body and the top surface of the substrate. The barrier layer is formed directly over the sheet-mold film, fully covers the sides of the die body, and extends horizontally beyond the flip-chip die.

### RELATED APPLICATIONS

This application claims the benefit of U.S. provisional patent application Ser. No. 63/670,302, filed on Jul. 12, 2024, the disclosure of which is hereby incorporated herein by reference in its entirety.

### FIELD OF THE DISCLOSURE

The present disclosure relates to a flip-chip based module and a process for making the same, and more particularly to a flip-chip based moisture-resistant module with an air-cavity at an active side of a flip-chip die, and a process to form the air gap within the flip-chip based module and to improve moisture-resistant characteristics of the flip-chip based module.

### BACKGROUND

Flip-chip assembly technology is widely utilized in semiconductor fabrication due to its short interconnect paths between a flip-chip die and a substrate, which eliminates the space needed for wire bonding and thus reduces the overall size of device modules. In addition, the elimination of wire bonds reduces undesired parasitic inductance, thereby making this module configuration attractive for high-frequency applications. However, capillary-dispensed underfill (CUF) materials or molded-underfill (MUF) materials, which fill a gap between an active region of the flip-chip die and the substrate to reduce coefficient of thermal expansion (CTE) mismatch stress, may negatively impact a high frequency electrical performance of the flip-chip die, especially for radio frequency (RF) performance. A total absence of underfill, alternatively, can have significant adverse implications for device reliability.

In addition, the reliability of the device modules may also be negatively impacted by external moisture in various ways, such as increasing dielectric losses, component cracks, delamination or volume expansion, and causing parametric instability.

Furthermore, as the operating speed of the flip-chip die increases, concentrated heat flux at the active region of the flip-chip die (e.g., a gallium nitride die) significantly increases. Effectively managing component heating and controlling junction temperatures becomes essential, given their potential to negatively impact performance and reliability. In the case of the high-power RF flip-chip die, the ability to dissipate large amounts of heat through the substrate underneath the flip-chip die (bottom-side cooling) is limited and insufficient. This limitation results in high thermal resistance, ultimately degrading the component's lifetime and/or the device's performance.

Accordingly, there remains a need for improved module designs, which utilize the flip-chip assembly for a small module size, avoid underfill materials for enhanced high frequency performance, and prevent or reduce moisture-induced damage. In addition, the improved module designs are also desired to provide an efficient path for heat dissipation of the high-power/high frequency flip-chip die.

### SUMMARY

The present disclosure relates to a flip-chip based moisture-resistant module with an air gap at an active side of a flip-chip die, and a process for making the same. The disclosed flip-chip based moisture-resistant module includes a substrate with a top surface, a flip-chip die, a sheet-mold film, and a barrier layer. The flip-chip die has a die body and a number of interconnects, each of which extends outward from a bottom surface of the die body and is attached to the top surface of the substrate. The sheet-mold film directly encapsulates sides of the die body, extends towards the top surface of the substrate, and directly adheres to the top surface of the substrate, such that an air-cavity with a perimeter defined by the sheet-mold film is formed between the bottom surface of the die body and the top surface of the substrate. The barrier layer is formed directly over the sheet-mold film, fully covers the sides of the die body, and extends horizontally beyond the flip-chip die.

In one embodiment of the flip-chip based moisture-resistant module, the sheet-mold film is formed of epoxy, resins, or a combination thereof. The barrier layer is formed of silicon oxide, silicon nitride, aluminum nitride, aluminum oxide, or parylene.

In one embodiment of the flip-chip based moisture-resistant module, each of the interconnects is a metal pillar, and each of the interconnects is attached to the top surface of the substrate via a solder joint.

According to one embodiment, the flip-chip based moisture-resistant module further includes a reinforcement layer, which is formed on the top surface of the substrate and encapsulates a bottom portion of each of the interconnects and its corresponding solder joint. Herein, the reinforcement layer is confined within the perimeter of the air cavity.

In one embodiment of the flip-chip based moisture-resistant module, the reinforcement layer includes a number of discrete sections, each of which encapsulates a corresponding one of the interconnects and the corresponding solder joint.

In one embodiment of the flip-chip based moisture-resistant module, the reinforcement layer is one contiguous section.

In one embodiment of the flip-chip based moisture-resistant module, the sheet-mold film extends horizontally beyond the flip-chip die without reaching the outermost periphery of the top surface of the substrate.

In one embodiment of the flip-chip based moisture-resistant module, the sheet-mold film extends horizontally beyond the flip-chip die and continues until the outermost periphery of the top surface of the substrate.

In one embodiment of the flip-chip based moisture-resistant module, the barrier layer completely covers the sheet-mold film.

In one embodiment of the flip-chip based moisture-resistant module, the barrier layer extends horizontally beyond the sheet-mold film, and a portion of the barrier layer is in contact with the top surface of the substrate.

In one embodiment of the flip-chip based moisture-resistant module, the barrier layer extends over the top surface of the substrate and continues until the outermost periphery of the top surface of the substrate.

In one embodiment of the flip-chip based moisture-resistant module, the barrier layer partially covers the sheet-mold film.

According to one embodiment, the flip-chip based moisture-resistant module further includes a mold compound. In this embodiment, the mold compound is formed over the top surface of the substrate and surrounds the flip-chip die via the sheet-mold film and the barrier layer. A top surface of the mold compound, a top surface of the die body, a tip surface of the sheet-mold film, and a tip surface of the barrier layer are at a flat coplanar level.

According to one embodiment, the flip-chip based moisture-resistant module further includes a heat spreader. The heat spreader is attached to the top surface of the die body via a spreader bonding layer. The heat spreader has a larger size than the die body in the horizontal plane, and fully covers the top surface of the die body, the tip surface of the sheet-mold film, and the tip surface of the barrier layer.

According to one embodiment, the flip-chip based moisture-resistant module further includes a spacer and a mold compound. In this embodiment, the spacer is attached to a top surface of the die body via a spacer bonding layer. The sheet-mold film also directly encapsulates sides of the spacer, and the barrier layer fully covers the sides of the spacer. The mold compound is formed over the top surface of the substrate and surrounds a combination of the spacer and the flip-chip die via the sheet-mold film and the barrier layer. A top surface of the mold compound, a top surface of the spacer, a tip surface of the sheet-mold film, and a tip surface of the barrier layer are at a flat coplanar level.

In one embodiment of the flip-chip based moisture-resistant module, the spacer has a same size as the die body in the horizontal plane, and the sides of the spacer are aligned with the sides of the die body, respectively.

In one embodiment of the flip-chip based moisture-resistant module, the spacer has a smaller size than the die body in the horizontal plane, such that the spacer partially covers the top surface of the die body. The sheet-mold film further directly covers portions of the top surface of the die body, which are not covered by the spacer.

According to one embodiment, the flip-chip based moisture-resistant module further includes a heat spreader attached to the top surface of the spacer via a spreader bonding layer. In this embodiment, the heat spreader is larger than the spacer in the horizontal plane, and fully covers the top surface of the spacer, the tip surface of the sheet-mold film, and the tip surface of the barrier layer.

In one embodiment of the flip-chip based moisture-resistant module, a top surface of the die body is metalized, and the spacer is formed of silicon carbon or silicon.

According to one embodiment, a communication device includes a control system, a baseband processor, receive circuitry, and transmit circuitry. In this embodiment, at least one or any combination of the control system, the baseband processer, the transmit circuitry, and the receive circuitry is implemented in a flip-chip based module, which includes a substrate, a flip-chip die, a sheet-mold film, and a barrier layer. The flip-chip die has a die body and a number of interconnects, each of which extends outward from a bottom surface of the die body and is attached to the top surface of the substrate. The sheet-mold film directly encapsulates sides of the die body, extends towards the top surface of the substrate, and directly adheres to the top surface of the substrate, such that an air-cavity with a perimeter defined by the sheet-mold film is formed between the bottom surface of the die body and the top surface of the substrate. The barrier layer is formed directly over the sheet-mold film, fully covers the sides of the die body, and extends horizontally beyond the flip-chip die.

According to one embodiment, a method of making a flip-chip based moisture-resistant module includes attaching a flip-chip die to a top surface of a substrate. The flip-chip die has a die body and a number of interconnects, each of which extends outward from a bottom surface of the die body and is attached to the top surface of the substrate. Next, a spacer is attached to a top surface of the die body. A sheet-mold film is then applied to encapsulate a combination of the spacer and the flip-chip die on the top surface of the substrate. The sheet-mold film is formed over a top surface of the spacer, extends downward along side surfaces of a combination of the spacer and the die body toward the top surface of the substrate, so as to establish an air cavity between the bottom surface of the die body and the top surface of the substrate, and directly adheres to the top surface of the substrate. A barrier layer is directly applied over the sheet-mold film. The barrier layer covers the top surface of the spacer and the side surfaces of the combination of the spacer and the die body, and extends horizontally beyond the flip-chip die. After both the sheet-mold film and the barrier layer are formed, a mold compound is formed over the top surface of the substrate to encapsulate a combination of the flip-chip die, the spacer, the sheet-mold film, and the barrier layer. A thinning step of the mold compound is followed. The mold compound is thinned down until the spacer is exposed. After the thinning step, a portion of the sheet-mold film over the top surface of the spacer and a portion of the barrier layer over the top surface of the spacer are completely removed. A retained portion of the sheet-mold film remains adhered to the side surfaces of the combination of the spacer and the die body, with a tip surface surrounding a top surface of the spacer and exposed through the mold compound. A retained portion of the barrier layer remains surrounding the combination of the spacer and the die body, with a tip surface surrounding the tip surface of the sheet-mold film and exposed through the mold compound.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary flip-chip based moisture-resistant module according to aspects of the present disclosure.

FIGS. 2A and 2B illustrate variations of the exemplary flip-chip based moisture-resistant module according to aspects of the present disclosure.

FIG. 3 is a flowchart showing a fabricating process of making the flip-chip based moisture-resistant module shown in FIG. 2A.

FIGS. 4A-4H illustrate steps associated with the fabricating process provided in FIG. 3.

FIG. 5 illustrates a block diagram of a communication device, which may include the flip-chip based moisture-resistant module illustrated in FIGS. 1-2B according to some embodiments of the present disclosure.

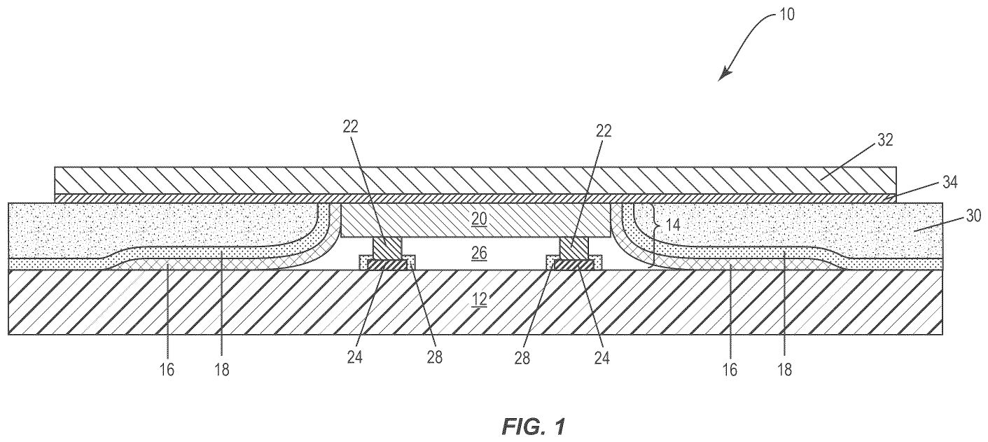

It will be understood that for clarity of illustration, FIGS. 1-5 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

FIG. 1 illustrates an exemplary flip-chip based module 10 with moisture-resistance according to some embodiments of the present disclosure. For the purpose of this illustration, the flip-chip based module 10 includes a substrate 12 having a top surface, a flip-chip die 14 attached to the top surface of the substrate 12, a sheet-mold film 16, and a barrier layer 18. In different applications, the flip-chip based module 10 may include more flip-chip dies 14.

The substrate 12 may be formed of laminate, ceramic, silicon, silicon carbon (SiC), or other chip carrier materials. A thickness of the substrate 12 is generally between 0.2 mm and 0.75 mm. The flip-chip die 14 may be a high-power and high-frequency die, such as a gallium nitride (GaN) die, a gallium arsenide (GaAs) die, a silicon die, an indium phosphide (InP) die, etc. The flip-chip die 14 includes a die body 20 (e.g., formed from gallium nitride) and a number of interconnects 22 extending outward from a bottom surface of the die body 20 towards the top surface of the substrate 12. Each interconnect 22 may be a metal pillar/bump (e.g., a copper bump, a gold bump, or a phosphor copper bump) and may be attached to the top surface of the substrate 12 via a solder joint 24. In some applications, each interconnect 22 may be a solder bump directly attached to the top surface of the substrate 12 (not shown). A height of each interconnect 22 is the same, between 20 μm and 125 μm.

The sheet-mold film 16 encapsulates sides of the die body 20 without contacting the bottom surface of the die body 20, extends towards the top surface of the substrate 12, and directly adheres to the top surface of the substrate 12. As such, an air-cavity 26 is formed under the die body 20 of the flip-chip die 14 (i.e., between the bottom surface of the die body 20 and the top surface of the substrate 12) and is surrounded by the sheet-mold film 16 (i.e., the sheet-mold film 16 defines a perimeter of the air-cavity 26). Typically, an active region of the flip-chip die 14 is located at a bottom portion of the die body 20 and transmits electrical signals toward the substrate 12 via the interconnects 22. Herein, the exposure of the bottom surface of the die body 20 and each interconnect 22 to the air-cavity 26 is beneficial for electronic performance of the flip-chip die 14, especially for high-frequency performance. Conventional underfill materials, which encapsulate the interconnect 22 and cover the bottom surface of the die body 20, are absent in the flip-chip based module 10.

The sheet mold film 16 may be formed of epoxy, resins, a combination thereof, or a similar combination. A thickness of the sheet mold film 16 depends on a thickness of the die body 20 and an associated height of the interconnects 22, typically between 50 μm and 800 μm. In addition to establishing the air-cavity 26, the sheet mold film 16 also protects the flip-chip die 14 against damage from the outside environment without significantly increasing the size of the flip-chip based module 10. In some applications, the sheet-mold film 16 extends horizontally beyond the flip-chip die 14 without reaching the periphery of the top surface of the substrate 12 (as illustrated in FIG. 1). In some applications, the sheet-mold film 16 extends horizontally beyond the flip-chip die 14 and continues until the outermost periphery of the top surface of the substrate 12 (not shown).

In order to reduce thermal stresses from coefficient of thermal expansion (CTE) mismatch on the interconnects 22 and consequently prevent the interconnects 22 from cracking due to the thermal stresses (especially for a flip-chip die with horizontal dimensions larger than ˜1 mm×˜1 mm), a reinforcement layer 28, which may be formed of Yincae SMT256, Senju EF100, Senju JPK9S or other similar formulations, may be provided around each interconnect 22. A thickness of the reinforcement layer 28 is typically between 5 μm and 50 μm. The reinforcement layer 28 is formed on the top surface of the substrate 12 and encapsulates each solder joint 24 and a bottom portion of each interconnect 22. Herein, the unencapsulated portion of each interconnect 22 typically forms the majority of each interconnect 22, thus the reinforcement layer 28 has a low impact on electrical signals propagating from the flip-chip die 14 to the substrate 12 and vice-versa. In some embodiments, the reinforcement layer 28 includes a number of discrete sections. Each discrete section of the reinforcement layer 28 surrounds a corresponding solder joint 24 and the bottom portion of a corresponding interconnect 22. In some embodiments, the reinforcement layer 28 is one contiguous section (not shown) and encapsulates each solder joint 24 and the bottom portion of each interconnect 22. Regardless of including the discrete sections or the contiguous section, the reinforcement layer 28 is always confined within the sheet-mold film 16 and does not extend outside of the perimeter of the air-cavity 26.

The barrier layer 18 is formed directly over the sheet-mold film 16 and configured to prevent/reduce moisture from an external environment of the flip-chip die 14. The barrier layer 18 might be formed of silicon oxide, silicon nitride, aluminum nitride, aluminum oxide, parylene, etc., with a thickness up to 5 μm (e.g., about 1 μm). In particular, the barrier layer 18 extends over the sides of the die body 20 (via the sheet-mold film 16) and toward the top surface of the substrate 12. In some applications, the barrier layer 18 fully covers the sheet-mold film 16 and extends over the top surface of the substrate 12 until the outermost periphery of the top surface of the substrate 12. If the sheet-mold film 16 does not reach the periphery of the top surface of the substrate 12, a portion of the barrier layer 18 will be formed directly on the top surface of the substrate 12 (as shown in FIG. 1). If the sheet-mold film 16 extends to the periphery of the top surface of the substrate 12, the barrier layer 18 will not be in contact with the top surface of the substrate 12 (not shown). In some applications, the barrier layer 18 extends horizontally beyond the flip-chip die 14 without reaching the periphery of the top surface of the substrate 12, where the barrier layer 18 might be larger than, equal to, or smaller than the sheet-mold film 16 (not shown). If the barrier layer 18 is larger than the sheet-mold film 16, there is a portion of the barrier layer 18 formed directly on the top surface of the substrate 12 (not shown). If the barrier layer 18 is equal to or smaller than the sheet-mold film 16, the barrier layer 18 will not be in contact with the top surface of the substrate 12 (not shown).

Herein, a strong adhesion of the sheet-mold film 16 to the sides of the flip-chip die 14 and to the top surface of the substrate 12 provides a well-sealed air-cavity 26. The sheet-mold film 16 together with the barrier layer 18 improves the moisture-resistant characteristics of the flip-chip based module 10.

In some embodiments, the flip-chip based module 10 may further include a mold compound 30 and a heat spreader 32. The mold compound 30 is formed over the top surface of the substrate 12 and surrounds the flip-chip die 14 via the sheet-mold film 16 and the barrier layer 18, while the heat spreader 32 is provided over the top surface of the flip-chip die 14. The mold compound 30 is configured to provide further protection to the flip-chip die 14 from the external environment and to provide further mechanical support to the heat spreader 32 above the flip-chip die 14.

Herein, the mold compound 30 does not cover a top surface of the die body 20 of the flip-chip die 14 and does not cover tip surfaces of the sheet-mold film 16 and the barrier layer 18, which surround the top surface of the die body 20 of the flip-chip die 14. A top surface of the mold compound 30, the top surface of the die body 20 of the flip-chip die 14, and the tip surfaces of the sheet-mold film 16 and the barrier layer 18 are at a flat coplanar level. There are no intentional air voids between the sides of the die body 20, the sheet-mold film 16, the barrier layer 18, and the mold compound 30.

With the barrier layer 18 extending toward the outermost periphery of the top surface of the substrate 12, the mold compound 30 is formed directly over the barrier layer 18 (as shown in FIG. 1). If the sheet-mold film 16 extends toward the outermost periphery of the top surface of the substrate 12 and the barrier layer 18 does not reach the outermost periphery of the top surface of the substrate 12, a portion of the mold compound 30 is formed directly over the barrier layer 18 and another portion of the mold compound 30 is formed directly over the sheet-mold film 16 (not shown). If neither of the sheet-mold film 16 nor the barrier layer 18 reaches the outermost periphery of the top surface of the substrate 12, a portion of the mold compound 30 is formed directly over the barrier layer 18, a portion of the mold compound 30 is formed directly over the top surface of the substrate 12, and optionally, a portion of the mold compound 30 is formed directly over the sheet-mold film 16 (if the sheet-mold film 16 extends horizontally beyond the barrier layer 18, not shown). The mold compound 30 may be an organic epoxy resin system or the like. A thickness of the mold compound depends on the thickness of the die body 20 and the associated height of the interconnects 22, typically between 150 μm and 1 mm.

The heat spreader 32 may have a larger size than the die body 20 of the flip-chip die 14 in the horizontal plane and may extend horizontally beyond the die body 20 of the flip-chip die 14. Preferably, the heat spreader 32 fully covers the top surface of the die body 20, fully covers the tip surfaces of the sheet-mold film 16 and the barrier layer 18, and resides over the top surface of the mold compound 30. As such, in addition to providing an upward heat dissipation path to the flip-chip die 14, the heat spreader 32 also provides extra sealing to the air-cavity 26 underneath the die body 20 of the flip-chip die 14 to address possible sealing defects due to unintentional air voids between the sides of the die body 20 and the sheet-mold film 16. In some embodiments, the heat spreader 32 might be attached to the top surface of the die body 20 via a first spreader bonding layer 34. The heat spreader 32 might be formed of SiC, copper, Molybdenum copper (CuMo), or other suitable high thermal conductivity materials. In one embodiment, the first spreader bonding layer 34 covers an entire bottom surface of the heat spreader 32 and has adequate thermal conductivity. The first spreader bonding layer 34 might be formed of a thermally conductive epoxy, a sintered or sinterable material (e.g., sintered silver or gold), a solder material, or other suitable adhesion material.

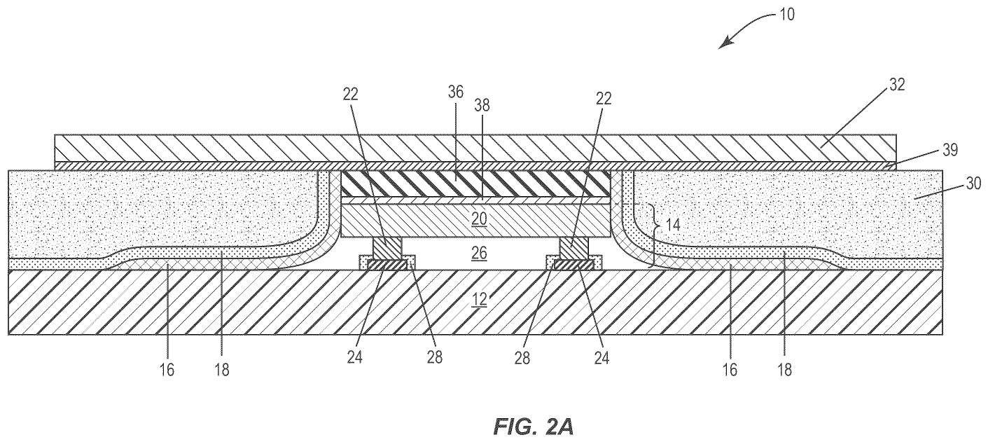

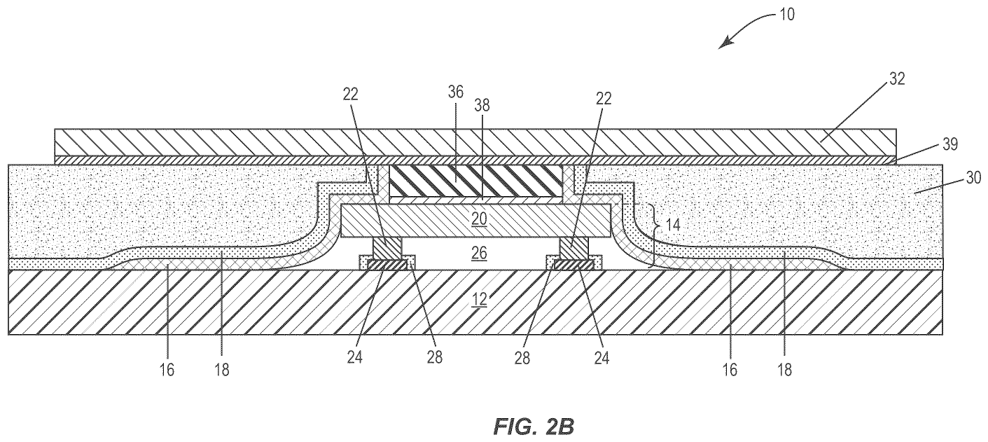

In some embodiments, the die body 20 of the flip-chip die 14 has a metalized top surface as a grounding plane, which may require a spacer 36 within the flip-chip based module 10, as illustrated in FIGS. 2A and 2B. The spacer 36 is configured to protect the metalized top surface of the die body 20 of the flip-chip die 14 during a fabrication process of the flip-chip based module 10 (more details are described in the following fabrication process description). Note that in the scenarios, if the top surface of the die body 20 of the flip-chip die 14 is not metalized, the flip-chip based module 10 may still include the spacer 36.

Herein, the spacer 36 is attached to the top surface of the die body 20 via a spacer bonding layer 38. The spacer 36 might be formed of SiC or silicon, with a thickness up to 1000 μm, or between 100 μm and 400 μm. The spacer bonding layer 38 might be formed of a thermally conductive epoxy, a sintered or sinterable material (e.g., sintered silver or gold), a solder material, or other suitable adhesion material. As shown in FIG. 2A, the spacer 36 might have a same size as the die body 20 of the flip-chip die 14 in the horizontal plane. Sides of the spacer 36 are aligned with the sides of the die body 20, respectively. In addition to the possible configurations of the sheet-mold film 16, the barrier layer 18, and the mold compound 30 described above (related to FIG. 1), the sheet-mold film 16 further directly covers the sides of the spacer 36, the barrier layer 18 further surrounds the spacer 36 via the sheet-mold film 16, and the mold compound 30 further surrounds the spacer 36 via the sheet-mold film 16 and the barrier layer 18. Herein, the mold compound 30 does not cover a top surface of the spacer 36 and still does not cover the tip surfaces of the sheet-mold film 16 and the barrier layer 18, which surround the top surface of the spacer 36. The top surface of the mold compound 30, the top surface of the spacer 36, and the tip surfaces of the sheet-mold film 16 and the barrier layer 18 are at a flat coplanar level.

In different applications, the spacer 36 might have a different size compared to the die body 20 of the flip-chip die 14 in the horizontal plane, as shown in FIG. 2B. For the purpose of this illustration, the spacer 36 is smaller than the die body 20 of the flip-chip die 14 in the horizontal plane. As such, the spacer 36 does not completely cover the entire top surface of the die body 20 of the flip-chip die 14. The sheet-mold film 16 directly encapsulates the sides of the spacer 36, extends directly over portions of the top surface of the die body 20 of the flip-chip die 14 (i.e., the portions of the top surface of the die body 20 are not covered by the spacer 36), directly encapsulates the sides of the die body 20 (without contacting the bottom surface of the die body 20), extends towards the top surface of the substrate 12, and directly adheres to the top surface of the substrate 12. The barrier layer 18 is formed directly over the sheet-mold film 16, and optionally, directly over a portion of the top surface of the substrate 12. The mold compound 30 is formed directly over the barrier layer 18, and optionally, directly over a portion of the sheet-mold film 16 and/or directly over a portion of the top surface of the substrate 12 (similar to the configurations of the barrier layer 18 and the mold compound 30 described above). Herein, the top surface of the mold compound 30, the top surface of the spacer 36, and the tip surfaces of the sheet-mold film 16 and the barrier layer 18 are at a flat coplanar level.

In different applications, the spacer 36 might be larger than the die body 20 of the flip-chip die 14 in the horizontal plane (not shown). The sheet-mold film 16 still directly encapsulates the sides of the spacer 36 and the sides of the die body 20 (without contacting the bottom surface of the die body 20), extends towards the top surface of the substrate 12, and directly adheres to the top surface of the substrate 12 (not shown). The barrier layer 18 and the mold compound 30 are formed in configurations similar to those described above.

Regardless of the size of the spacer 36, the top surface of the mold compound 30, the top surface of the spacer 36, and the tip surfaces of the sheet-mold film 16 and the barrier layer 18 are at a flat coplanar level. There are no intentional air voids between the sides of the spacer 36, the sheet-mold film 16, the barrier layer 18, and the mold compound 30, and there are no intentional air voids between the sides of the die body 20, the sheet-mold film 16, the barrier layer 18, and the mold compound 30. The heat spreader 32 may have a larger size than the spacer 36 in the horizontal plane, and may extend horizontally beyond the spacer 36. Preferably, the heat spreader 32 fully covers the top surface of the spacer 36, fully covers the tip surfaces of the sheet-mold film 16 and the barrier layer 18, and resides over the top surface of the mold compound 30. As such, the heat spreader 32 can provide extra sealing to the air-cavity 26 underneath the die body 20 of the flip-chip die 14 to address possible sealing defects due to unintentional air voids between the sides of the spacer 36 and the sheet-mold film 16. The heat spreader 32 might be attached to the top surface of the spacer 36 via a second spreader bonding layer 39. In one embodiment, the second spreader bonding layer 39 covers the entire bottom surface of the heat spreader 32 and has adequate thermal conductivity. The second spreader bonding layer 39 might be formed of a thermally conductive epoxy, a sintered or sinterable material (e.g., sintered silver or gold), a solder material, or other suitable adhesion material. The second spreader bonding layer 39 might be the same as or different from the first spreader bonding layer 34.

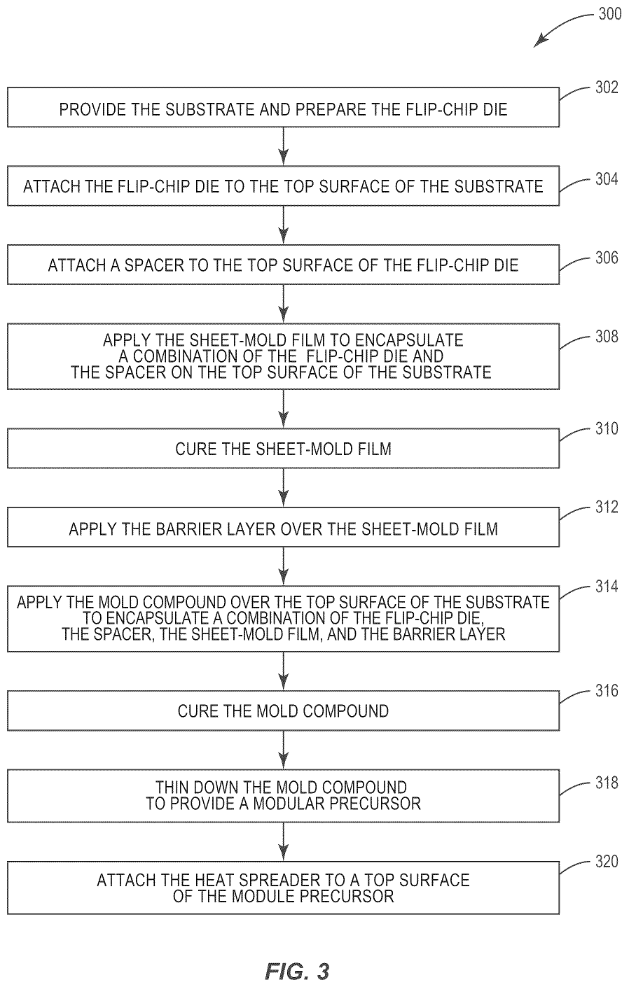

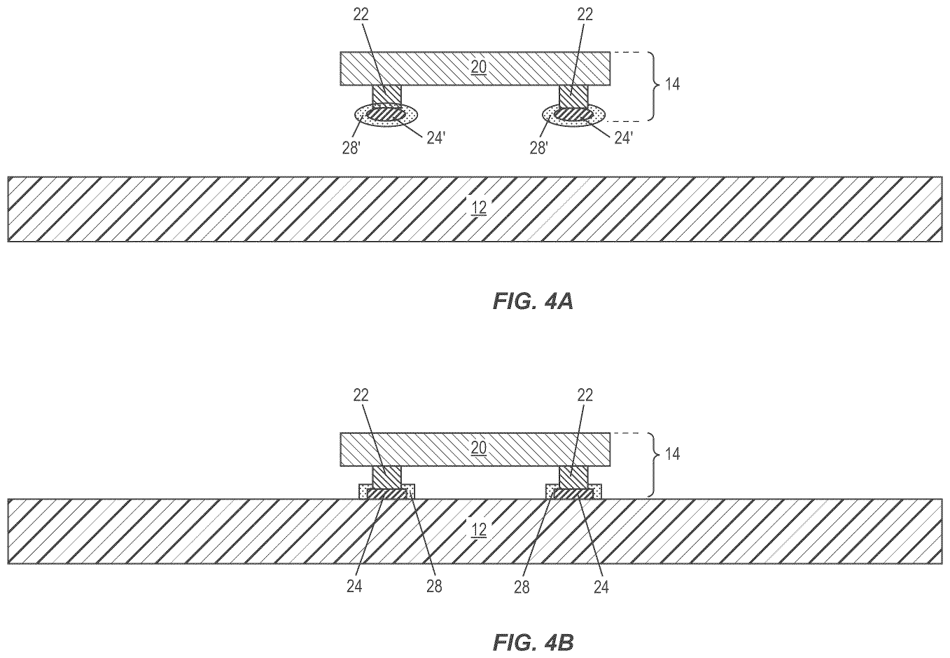

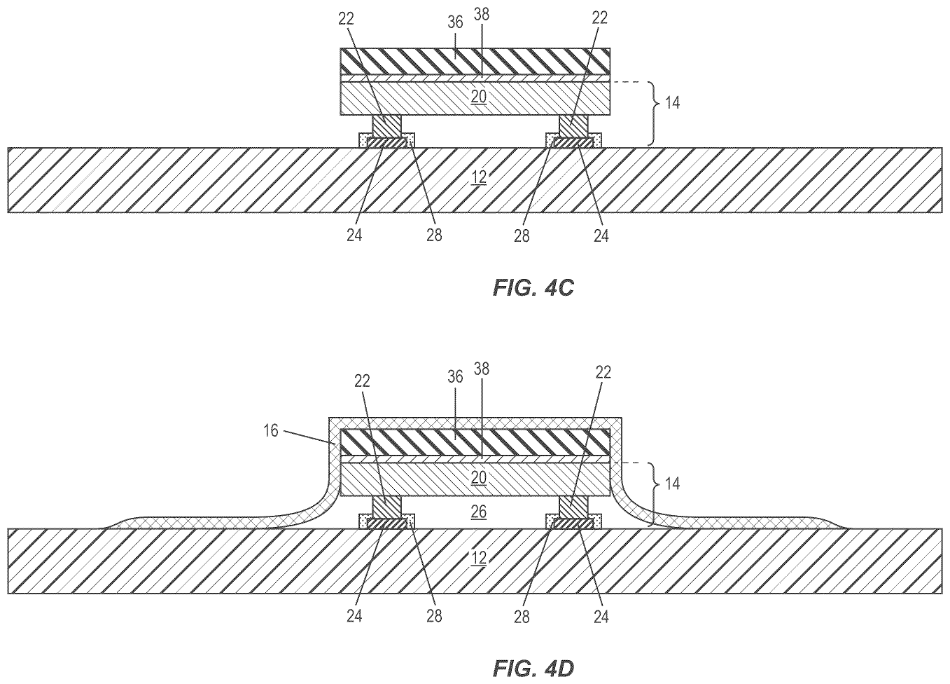

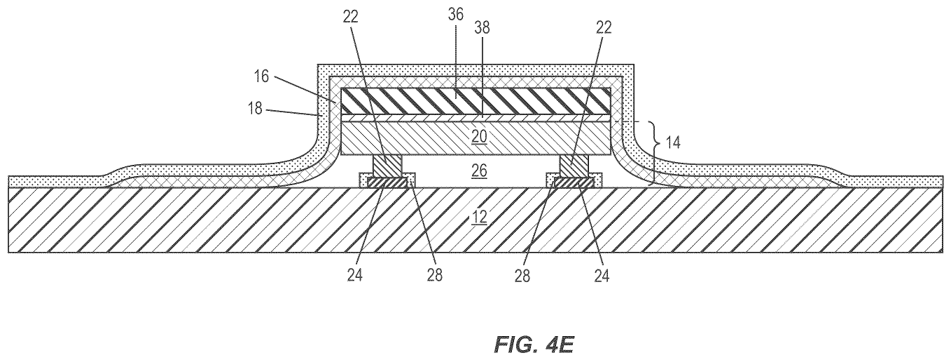

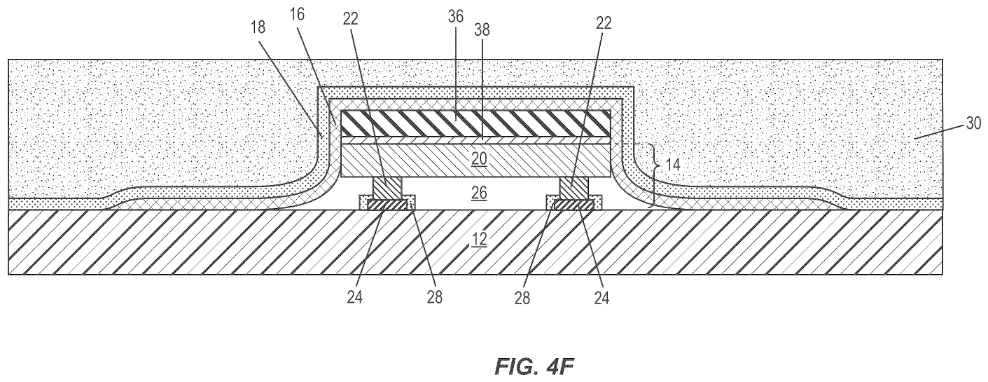

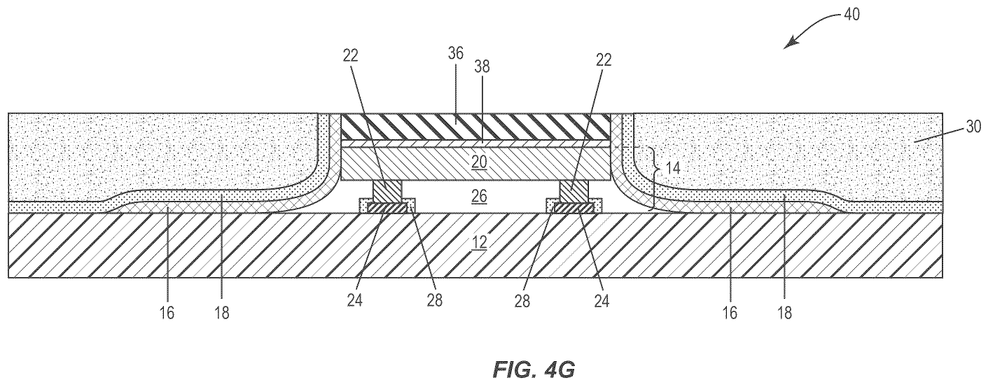

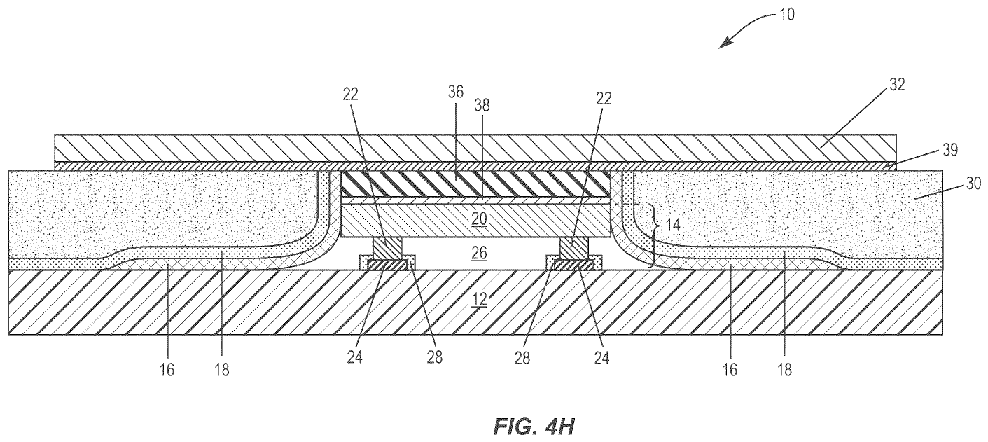

FIG. 3 provides a flow diagram that illustrates an exemplary process 300 for fabricating the flip-chip based module 10 shown in FIG. 2A according to some embodiments of the present disclosure. FIGS. 4A-4H illustrate the steps associated with the fabricating process 300 provided in FIG. 3. Although the flow diagram and the associated steps are illustrated in a series, they are not necessarily order dependent. Some steps may be done in a different order than that presented. Further, processes within the scope of this disclosure may include fewer or more steps than those illustrated in FIG. 3 and FIGS. 4A-4H.

Initially, the substrate 12 is provided and the flip-chip die 14 is prepared with solder caps 24′ (step 302), as depicted in FIG. 4A. The flip-chip die 14 has the die body 20 and the interconnects 22 extending outward from the bottom surface of the die body 20, and each solder cap 24′ is formed at the bottom portion of a corresponding interconnect 22. For the purpose of this illustration, there is only one flip-chip die 14 provided. In different applications, multiple flip-chip dice may be prepared for the flip-chip based module 10. In some embodiments, the preparation of the flip-chip die 14 also includes applying a reinforcement material 28′ to encapsulate each solder cap 24′ and the bottom portion of each interconnect 22.

Next, the flip-chip die 14 is attached to the top surface of the substrate 12 (step 304), as illustrated in FIG. 4B. Herein, the solder cap 24′ for each interconnect 22 is reflowed and converted to the solder joint 24, such that the interconnects 22 of the flip-chip die 14 are securely connected to the substrate 12. Reflowing the solder caps 24′ may be provided by heating in a furnace. In the meantime, the reinforcement material 28′ may be cured to form a reinforcement layer 28 by the same heating step. In some applications, reflowing the solder caps 24′ and curing the reinforcement material 28′ may be accomplished separately. Herein, the cured reinforcement layer 28 may have a number of discrete sections. Each discrete section of the reinforcement layer 28 encapsulates a corresponding solder joint 24 and the bottom portion of a corresponding interconnect 22. The reinforcement layer 28 provides a clean surface for reflowing the solder caps 24′ and provides superior reinforcement to each interconnect 22.

The spacer 36 is then attached to the top surface of the die body 20 of the flip-chip die 14 via the spacer bonding layer 38 (step 306), as illustrated in FIG. 4C. The spacer 36 might be formed of a highly thermal conductive material, such as SiC or silicon, so that the spacer 36 does not significantly increase the thermal resistance of the upward heat dissipation path for the flip-chip die 14. For the purpose of this illustration, the spacer 36 has the same size as the die body 20 of the flip-chip die 14 in the horizontal plane, and the sides of the spacer 36 are aligned with the sides of the die body 20, respectively. In different applications, the spacer 36 might have a different size (e.g., a smaller or larger size) compared to the die body 20 of the flip-chip die 14 in the horizontal plane (not shown).

After the spacer 36 is attached to the flip-chip die 14, the sheet-mold film 16 is applied to encapsulate a combination of the flip-chip die 14 and the spacer 36 on the top surface of the substrate 12 (step 308), as illustrated in FIG. 4D. The sheet-mold film 16 is formed over the top surface of the spacer 36, down side surfaces of a combination of the spacer 36 and the die body 20 and, and toward the top surface of the substrate 12 to establish the perimeter of the air cavity 26, and directly adheres to the top surface of the substrate 12. Herein, the active region of the flip-chip die 14 (located at the bottom portion of the die body 20) and the majority of each interconnect 22 are exposed in the air cavity 26, which is beneficial for electronic performance of the flip-chip die 14, especially for high-frequency performance. The sheet mold film 16 formed of epoxy, resin, a combination thereof, or other suitable materials is realized by a sheet molding process.

For the purpose of this illustration, the sheet-mold film 16 extends horizontally beyond the flip-chip die 14 without reaching the periphery of the top surface of the substrate 12, and a portion of the top surface of the substrate 12 is exposed through the sheet-mold film 16. In different applications, the sheet-mold film 16 may extend horizontally beyond the flip-chip die 14 and continues until the outermost periphery of the top surface of the substrate 12 (not shown). A curing process (step 310, not shown) is then used to harden the sheet-mold film 16. The curing temperature is between 75° C. and 250° C. depending on which material is used as the sheet-mold film 16.

Next, the barrier layer 18 is applied over the sheet-mold film 16 (step 312), as illustrated in FIG. 4E. The barrier layer 18 also covers the top surface of the spacer 36 and the side surfaces of the combination of the spacer 36 and the die body 20, extends toward the top surface of the substrate 12, and extends horizontally beyond the flip-chip die 14 to cover a portion of the top surface of the substrate 12. The barrier layer 18, which might be formed of silicon oxide, silicon nitride, aluminum nitride, aluminum oxide, parylene, etc., is provided by an atomic layer deposition (ALD) process. The barrier layer 18 is configured to prevent/reduce moisture from the external environment of the flip-chip die 14.

For the purpose of this illustration, the barrier layer 18 fully covers the sheet-mold film 16 and extends over the top surface of the substrate 12 until the outermost periphery of the top surface of the substrate 12. In different applications, the barrier layer 18 may not fully cover the sheet-mold film 16 (but still extends horizontally beyond the flip-chip die 14), such that a portion of the sheet-mold film 16 is exposed through the barrier layer 18.

The mold compound 30 is then applied over the top surface of the substrate 12 to encapsulate a combination of the flip-chip die 14, the spacer 36, the sheet-mold film 16, and the barrier layer 18 (step 314), as illustrated in FIG. 4F. The mold compound 30 may be applied by various procedures, such as overmolding, compression molding, transfer molding, dam fill encapsulation, or screen print encapsulation. A second curing process (step 316, not shown) is then used to harden the mold compound 30. The curing temperature is between 100° C. and 320° C. depending on which material is used as the mold compound 30.

Next, the mold compound 30 is thinned down to provide a module precursor 40 (step 318), as illustrated in FIG. 4G. Herein, the mold compound 30 is thinned down until the spacer 36 is exposed. Since the sheet-mold film 16 and the barrier layer 18 cover the top surface of the spacer 36, the thinning process also removes a portion of the sheet-mold film 16 over the top surface of the spacer 36, a portion of the barrier layer 18 over the top surface of the spacer 36, and optionally a portion of the spacer 36. The thinning process does not disturb the top surface of the die body 20 of the flip-chip die 14. The sheet-mold film 16 remains adhered to the side surfaces of the combination of the spacer 36 and the die body 20 of the flip-chip die 14, and the barrier layer 18 and the mold compound 30 still surround the combination of the spacer 36 and the die body 20 of the flip-chip die 14. As such, the air cavity 26 is still sealed. This thinning process may be done with a mechanical grinding process. After the grinding, the module precursor 40 has a flat top surface, which is composed of the top surface of the mold compound 30, the top surface of the spacer 36, and the tip surfaces of the sheet-mold film 16 and the barrier layer 18.

Lastly, the heat spreader 32 is attached to the top surface of the module precursor 40 to complete the flip-chip based module 10 (step 320), as illustrated in FIG. 4H. The heat spreader 32 might be attached to the top surface of the module precursor 40 via the second spreader bonding layer 39. Herein, the heat spreader 32 has a larger size than the spacer 36 in the horizontal plane, and fully covers the top surface of the spacer 36 and the tip surfaces of the sheet-mold film 16 and the barrier layer 18. As such, in addition to providing the upward heat dissipation path from the flip-chip die 14 (via the spacer 36), the heat spreader 32 also provides extra sealing to the air-cavity 26 underneath the die body 20 of the flip-chip die 14. The extra sealing addresses possible sealing defects due to unintentional air voids between the sheet-mold film 16 and the sides of the combination of the spacer 36 and the die body 20.

The systems and methods for a flip-chip based moisture-resistant module with an air-cavity at an active side of a flip-chip die, according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

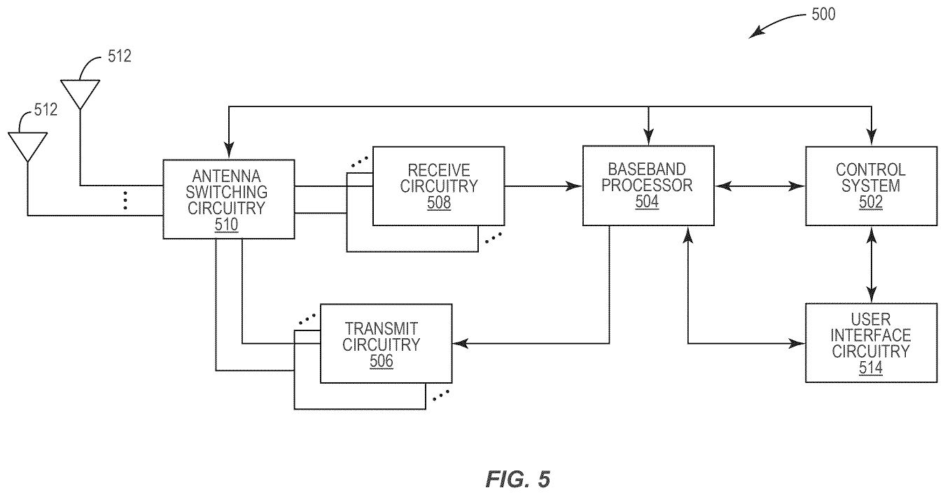

With reference to FIG. 5, the concepts described above may be implemented in various types of communication devices 500, such as those listed in the previous paragraph. The communication device 500 will generally include a control system 502, a baseband processor 504, transmit circuitry 506, receive circuitry 508, and user interface circuitry 514. Optionally, if the communication device 500 is a radio frequency device, the communication device 500 may further include antenna switching circuitry 510 and multiple antennas 512. Herein, at least one or any combination of the control system 502, the baseband processor 504, the transmit circuitry 506, and the receive circuitry 508 may be implemented in the flip-chip based module 10 (e.g. implemented in the flip-chip die 14) as illustrated in FIGS. 1-2B.

In a non-limiting example, the control system 502 can be a field-programmable gate array (FPGA) or an application-specific integrated circuit (ASIC), as an example. In this regard, the control system 502 can include at least a microprocessor(s), an embedded memory circuit(s), and a communication bus interface(s). The receive circuitry 508 receives radio frequency signals via the antennas 512 and through the antenna switching circuitry 510 from one or more base stations. A low noise amplifier and a filter of the receive circuitry 508 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 504 processes the digitized received signal to extract the information or data bits conveyed in the received signal. This processing typically comprises demodulation, decoding, and error correction operations, as will be discussed in greater detail below. The baseband processor 504 is generally implemented in one or more digital signal processors (DSPs) and ASICs.

For transmission, the baseband processor 504 receives digitized data, which may represent voice, data, or control information, from the control system 502, which it encodes for transmission. The encoded data is output to the transmit circuitry 506, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 512 through the antenna switching circuitry 510. The multiple antennas 512 and the replicated transmit and receive circuitries 506, 508 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A flip-chip based module comprising:
a substrate with a top surface;
a flip-chip die having a die body and a plurality of interconnects, each of which extends outward from a bottom surface of the die body and is attached to the top surface of the substrate;
a sheet-mold film that directly encapsulates sides of the die body, extends towards the top surface of the substrate, and directly adheres to the top surface of the substrate, such that an air-cavity with a perimeter defined by the sheet-mold film is formed between the bottom surface of the die body and the top surface of the substrate; and
a barrier layer formed directly over the sheet-mold film, fully covering the sides of the die body, and extending horizontally beyond the flip-chip die.

2. The flip-chip based module of claim 1, wherein:
the sheet-mold film is formed of epoxy, resins, or a combination thereof; and
the barrier layer is formed of silicon oxide, silicon nitride, aluminum nitride, aluminum oxide, or parylene.

3. The flip-chip based module of claim 1, wherein:
each of the plurality of interconnects is a metal pillar; and
each of the plurality of interconnects is attached to the top surface of the substrate via a solder joint.

4. The flip-chip based module of claim 3, further comprising a reinforcement layer, which is formed on the top surface of the substrate and encapsulates a bottom portion of each of the plurality of interconnects and its corresponding solder joint, wherein the reinforcement layer is confined within the perimeter of the air cavity.

5. The flip-chip based module of claim 4, wherein the reinforcement layer includes a plurality of discrete sections, each of which encapsulates a bottom portion of a corresponding one of the plurality of interconnects and the corresponding solder joint.

6. The flip-chip based module of claim 4, wherein the reinforcement layer is one contiguous section.

7. The flip-chip based module of claim 1, wherein the sheet-mold film extends horizontally beyond the flip-chip die without reaching the outermost periphery of the top surface of the substrate.

8. The flip-chip based module of claim 1, wherein the sheet-mold film extends horizontally beyond the flip-chip die and continues until the outermost periphery of the top surface of the substrate.

9. The flip-chip based module of claim 1, wherein the barrier layer completely covers the sheet-mold film.

10. The flip-chip based module of claim 9, wherein the barrier layer extends horizontally beyond the sheet-mold film and a portion of the barrier layer is in contact with the top surface of the substrate.

11. The flip-chip based module of claim 9, wherein the barrier layer extends over the top surface of the substrate and continues until the outermost periphery of the top surface of the substrate.

12. The flip-chip based module of claim 1, wherein the barrier layer partially covers the sheet-mold film.

13. The flip-chip based module of claim 1, further comprising a mold compound, wherein:
the mold compound is formed over the top surface of the substrate and surrounds the flip-chip die via the sheet-mold film and the barrier layer; and
a top surface of the mold compound, a top surface of the die body, a tip surface of the sheet-mold film, and a tip surface of the barrier layer are at a flat coplanar level.

14. The flip-chip based module of claim 13, further comprising a heat spreader, wherein:
the heat spreader is attached to the top surface of the die body via a spreader bonding layer; and
the heat spreader has a larger size than the die body in the horizontal plane, and fully covers the top surface of the die body, the tip surface of the sheet-mold film, and the tip surface of the barrier layer.

15. The flip-chip based module of claim 1, further comprising a spacer and a mold compound, wherein:
the spacer is attached to a top surface of the die body via a spacer bonding layer;
the sheet-mold film directly encapsulates sides of the spacer, and the barrier layer fully covers the sides of the spacer;
the mold compound is formed over the top surface of the substrate and surrounds a combination of the spacer and the flip-chip die via the sheet-mold film and the barrier layer; and
a top surface of the mold compound, a top surface of the spacer, a tip surface of the sheet-mold film, and a tip surface of the barrier layer are at a flat coplanar level.

16. The flip-chip based module of claim 15, wherein the spacer has a same size as the die body in the horizontal plane, and the sides of the spacer are aligned with the sides of the die body, respectively.

17. The flip-chip based module of claim 15, wherein:
the spacer has a smaller size than the die body in the horizontal plane, such that the spacer partially covers the top surface of the die body; and
the sheet-mold film further directly covers portions of the top surface of the die body, which are not covered by the spacer.

18. The flip-chip based module of claim 15, further comprising a heat spreader, wherein:
the heat spreader is attached to the top surface of the spacer via a spreader bonding layer; and
the heat spreader has a larger size than the spacer in the horizontal plane, and fully covers the top surface of the spacer, the tip surface of the sheet-mold film, and the tip surface of the barrier layer.

19. The flip-chip based module of claim 15, wherein:
a top surface of the die body is metalized; and
the spacer is formed of silicon carbon or silicon.

20. A communication device comprising:
a control system;
a baseband processor;
receive circuitry; and
transmit circuitry, wherein at least one or any combination of the control system, the baseband processer, the transmit circuitry, and the receive circuitry is implemented in a flip-chip based module, which includes a substrate, a flip-chip die, a sheet-mold film, and a barrier layer, wherein:
the flip-chip die has a die body and a plurality of interconnects, each of which extends outward from a bottom surface of the die body and is attached to a top surface of the substrate;
the sheet-mold film directly encapsulates sides of the die body, extends towards the top surface of the substrate, and directly adheres to the top surface of the substrate, such that an air-cavity with a perimeter defined by the sheet-mold film is formed between the bottom surface of the die body and the top surface of the substrate; and
the barrier layer is formed directly over the sheet-mold film, fully covers the sides of the die body, and extends horizontally beyond the flip-chip die.

21. A method comprising:
attaching a flip-chip die to a top surface of a substrate, wherein the flip-chip die has a die body and a plurality of interconnects, each of which extends outward from a bottom surface of the die body and is attached to the top surface of the substrate;
attaching a spacer to a top surface of the die body;
applying a sheet-mold film to encapsulate a combination of the spacer and the die body on the top surface of the substrate, wherein the sheet-mold film is formed over a top surface of the spacer, extends downward along side surfaces of the combination of the spacer and the die body toward the top surface of the substrate, so as to establish an air cavity between the bottom surface of the die body and the top surface of the substrate, and directly adheres to the top surface of the substrate;
applying a barrier layer directly over the sheet-mold film, wherein the barrier layer covers the top surface of the spacer and the side surfaces of the combination of the spacer and the die body, and extends horizontally beyond the flip-chip die;
applying a mold compound over the top surface of the substrate to encapsulate a combination of the flip-chip die, the spacer, the sheet-mold film, and the barrier layer; and
thinning down the mold compound until the spacer is exposed, wherein:
a portion of the sheet-mold film over the top surface of the spacer and a portion of the barrier layer over the top surface of the spacer are completely removed;
a retained portion of the sheet-mold film remains adhered to the side surfaces of the combination of the spacer and the die body, with a tip surface surrounding a top surface of the spacer and exposed through the mold compound; and
a retained portion of the barrier layer remains surrounding the combination of the spacer and the die body, with a tip surface surrounding the tip surface of the sheet-mold film and exposed through the mold compound.
